(19) United States
(12) Patent Application Publication
(10) Pub. No.: US 2009/0272418 A1
(43) Pub. Date: Nov. 5, 2009

(54) THERMOELECTRIC GENERATOR DEVICE

(76) Inventors: Tehng-Lung Kuo, Wai Hai town Jianmen (CN); Jen-Chun Chang, Wai Hai town Jianmen (CN)

Correspondence Address: LEONG C LEI, PMB # 1008, 1867 YGNACIO VALLEY ROAD, WALNUT CREEK, CA, 94598, US

(21) Appl. No.: 12/111,982

(22) Filed: Apr. 30, 2008

(51) Int. Cl. H01L 35/02; H01L 35/20

(52) U.S. Cl. 136/205; 136/241

(57) ABSTRACT

A thermoelectric generator includes an enclosure accommodating therein multiple segments of anode thermoelectric material and multiple segments of cathode thermoelectric material, both having low thermal conductivity. The anode thermoelectric material segments are respectively jointed to the corresponding ones of the cathode thermoelectric material segments to form a plurality of V-shaped electrode pairs each having an apex. The plurality of V-shaped electrode pairs is connected in cascade to form a serially connected sequence with the apexes of the V-shaped electrode pairs of the sequence set in a common given direction. A conductive lead is connected to each of a first one and a last one of the plurality V-shaped electrode pairs of the sequence and extends out of the enclosure. The generator can be directly put in a flame or a high temperature environment and can bear a maximum temperature beyond 1000° C. without additionally mounted heat dissipation device.

### BACKGROUND OF THE INVENTION

(a) Technical Field of the Invention

The present invention relates to a power generation device, and in particular to a thermoelectric generator.

(b) Description of the Prior Art

A thermoelectric generator, which is currently available in the market, is formed by combining two different types of semiconductor materials, respectively serving as “cold” surface and “hot” surface. The hot surface detects and receives high temperature, while the cold surface dissipates the thermal energy transmitted from the hot surface. When a temperature difference between the hot and cold surfaces is maintained, such as more than 60° C., an electromotive force is induced between the hot and cold surfaces. The conventional thermoelectric generator suffers certain drawbacks. For example, the conventional thermoelectric generator cannot be put in direct contact with a flame. Further, the maximum temperature that the hot surface can bear cannot exceed 200° C. In addition, the thermoelectric generator or the likes conduct heat very fast so that additional heat dissipation device must be provided to the cold surface and measures including forced air cooling, water cooling, hydraulic cooling, or other known cooling means must be adopted to ensure the heat transmitted from the hot surface can be timely removed to maintain the temperature difference between the hot and cold surfaces and thus ensure the desired performance and efficiency. Due to such problems, the thermoelectric generators are almost used only in high-tech products or laboratories and have complicated constructions with high manufacturing costs.

### SUMMARY OF THE INVENTION

The primary purpose of the present invention is to provide a thermoelectric generator device that has a heat receiving terminal positionable in a high temperature and that can ensure proper operation without additional heat dissipation device, so as to have a simplified construction.

A solution to the above problems in accordance with the present invention comprises a thermoelectric generator device, which comprises an enclosure inside which multiple segments of anode thermoelectric material and multiple segments of cathode thermoelectric material, both having low thermal conductivity, are arranged in such a way that the anode thermoelectric material segments are respectively jointed to the corresponding cathode thermoelectric material segments to form a plurality of V-shaped electrode pairs, which are connected in cascade with top apexes set in the same direction. First and last V-shaped electric pairs are respectively connected to leads that extend out of the enclosure.

As a different solution to the problems, in accordance with the present invention, the enclosure is made in a step-like construction having a first, reduced portion and a opposite second portion, wherein the first portion accommodates the top apexes of the V-shaped electrode pairs and has a thickness (or height) smaller than the second portion.

As a further different solution to the problems, in accordance with the present invention, the anode thermoelectric material comprises a nickel-chromium alloy and the cathode thermoelectric material comprises a copper-nickel alloy. Further, the enclosure is made of a temperature resistant metal or ceramics.

The effectiveness of the present invention is that with the above described arrangement, the thermoelectric generator of the present invention can be used by being directly put in a flame or in a high temperature environment. The maximum temperature that the thermoelectric generator of the present invention can bear can be higher than 1000° C. Further, no additional heat dissipation device is required for maintaining normal operation of the thermoelectric generator so that the construction is simplified and the manufacturing costs are reduced.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a cross-sectional view showing a thermoelectric generator constructed in accordance with the present invention;

FIG. 2 is a schematic top view illustrating the arrangement of the thermoelectric generator of the present invention; and

FIG. 3 is a schematic view illustrating the connection among segments of thermoelectric materials in the thermoelectric generator in accordance with the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

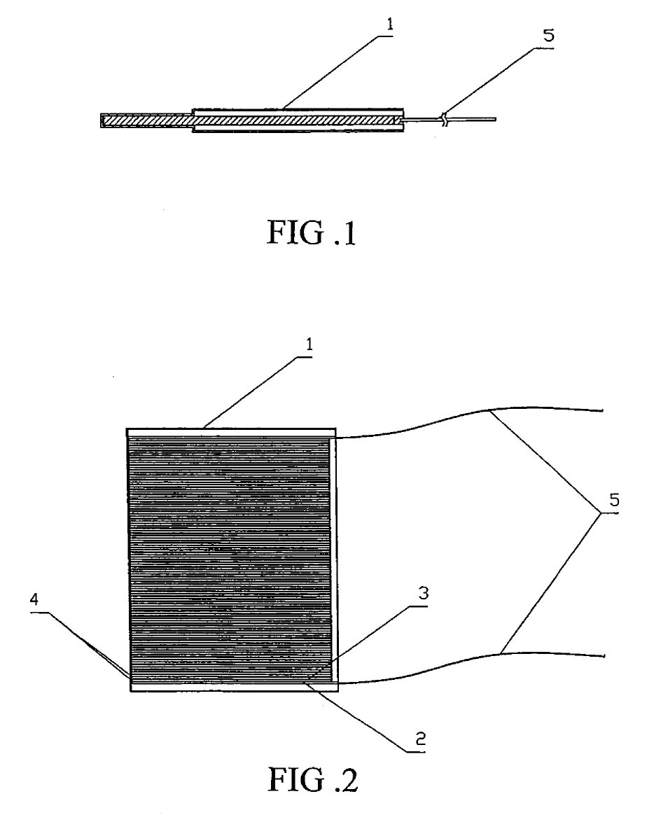

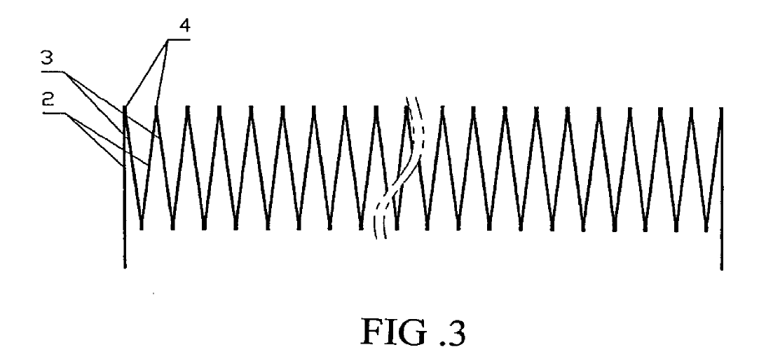

With reference to the drawings and in particular to FIGS. 1 to 3, the present invention provides a thermoelectric generator device comprising an enclosure 1 inside which multiple segments of anode thermoelectric material 2 and multiple segments of cathode thermoelectric material 3, both having low thermal conductivity, are accommodated. The anode thermoelectric material segments 2 and the cathode thermoelectric material segments 3 are respectively jointed together to form a plurality of V-shaped electrode pairs each having a top apex 4. The V-shaped electrode pairs are connected in cascade to form a serially connected sequence of the V-shaped electrode pairs with the apexes 4 set at the same direction. A conductive lead 5 is connected to both the first one and the last one of the electrode pair sequence and extends out of the enclosure 1. In operation, the portion of the enclosure 1 that accommodates the apexes 4 of the V-shaped electrode pairs is put in a flame or in a high temperature environment and electrical voltage is induced between the conductive leads 5. The level of the voltage induced between the conductive leads 5 is adjustable by changing the number of the V-shaped electrode pairs connected in the sequence. An example range of adjustment of the output voltage is around 0.001V-24V The thermoelectric generator in accordance with the present invention can be directly put in a flame for use and, in a preferred embodiment of the present invention, the maximum temperature that the thermoelectric generator can bear is higher than 1000° C. A particular application of the thermoelectric generator of the present invention is to be incorporated with an outdoor barbeque oven. Due to the inconvenience and unavailability of power supply in an outdoor environment, an electric appliance can only be powered by a built-in power source, such as a DC battery, which is of very limited power supply and has to be frequently replaced or recharged. By incorporating the thermoelectric generator of the present invention with a barbeque oven or the likes, power can be generated during barbequing and such power can be used to drive the electric appliance or to charge the built-in power source of the electric appliance. The inconvenience of frequent replacement of the built-in power source can be saved. Further, the thermoelectric materials adopted in the thermoelectric generator of the present invention have low thermal conductivity, making it possible to maintain a proper temperature difference between the cold side and the hot side without additionally mounted head dissipation device, whereby the construction can be simplified and the manufacturing costs are reduced.

In the embodiment illustrated, the enclosure 1 is made a step-like construction having a reduced, first portion and an opposite, second portion jointed together to form the step therebetween. The reduced portion accommodates the apexes 4 of the V-shaped electrode pairs and has a thickness (or height) smaller than the second portion. With the step-like construction, when used, the enclosure 1 can be stably set with the reduced portion positioned in a high temperature location and the second portion exposed to the outside. Positioning of the thermoelectric generator of the present invention by means of the step-like construction allows the thermoelectric generator to be conveniently and easily installed.

In accordance with a preferred embodiment of the present invention, the anode thermoelectric material 2 comprises a nickel-chromium alloy and the cathode thermoelectric material 3 comprises a copper-nickel alloy. These materials allow the thermoelectric generator of the present invention to produce an optimum thermal electromotive force and make the thermoelectric generator insensitive to corrosion induced by high humidity environment and thus allowing the thermoelectric generator to be applicable to high humidity environment. The above mentioned thermoelectric materials also feature excellent stability and excellent resistance against oxidization, allowing application of the thermoelectric generator of the present invention in oxidative atmospheres and inert gas atmospheres, and are of low material costs.

In a preferred embodiment of the present invention, the enclosure 1 is made of a temperature resistant metal or ceramics, so the enclosure 1 can be put in continuous operation in a high temperature environment and can be of extended service life, ensuring the protection of the thermoelectric materials against damages.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A thermoelectric generator comprising an enclosure (1) accommodating therein multiple segments of anode thermoelectric material (2) and multiple segments of cathode thermoelectric material (3), both having low thermal conductivity, the anode thermoelectric material segments (2) being respectively jointed to corresponding one of the cathode thermoelectric material segments (3) to form a plurality of V-shaped electrode pairs each having an apex (4), the plurality of V-shaped electrode pairs being connected in cascade to form a serially connected sequence, the apexes (4) of the V-shaped electrode pairs of the sequence being set in a common given direction, a conductive lead (5) being connected to each of a first one and a last one of the plurality V-shaped electrode pairs of the sequence and extending out of the enclosure (1).

2. The thermoelectric generator as claimed in claim 1, wherein the enclosure (1) has a step-like configuration comprising a reduced portion in which the apexes (4) of the V-shaped electrode pairs of the sequence are accommodated.

3. The thermoelectric generator as claimed in claim 1 or 2, wherein the anode thermoelectric material (2) comprises a nickel-chromium alloy and wherein the cathode thermoelectric material (3) comprises a copper-nickel alloy.

4. The thermoelectric generator as claimed in claim 1, wherein the enclosure (1) is made of a temperature resistant metal or ceramics.
